(19) United States
(12) Patent Application Publication
(10) Pub. No.: US 2022/0038117 A1
(43) Pub. Date: Feb. 3, 2022

(54) DEVICE AND METHOD FOR TRANSMITTING DATA BY USING MULTILEVEL CODING, AND COMMUNICATION SYSTEM

(71) Applicant: FUJITSU LIMITED, Kawasaki-shi (JP)

(72) Inventors: Junichi Sugiyama, Kawasaki (JP); Toshihiro Konno, Sendai (JP)

(73) Assignee: FUJITSU LIMITED, Kawasaki-shi (JP)

(21) Appl. No.: 17/197,091

(22) Filed: Mar. 10, 2021

(30) Foreign Application Priority Data
Jul. 31, 2020 (JP) 2020-129933

(51) Int. Cl. H03M 13/29; H04L 27/34

(52) U.S. Cl. CPC H03M 13/2906; H04L 27/345

(57) ABSTRACT

A communication device includes a modulator, a first encoder and a second encoder, and generates a modulated signal with quadrature amplitude modulation. The modulator generates a modulated signal by mapping each symbol in a data frame that includes data, a first code, and a second code to a signal point among signal points of the quadrature amplitude modulation. The first encoder encodes the data by using a first coding scheme to generate the first code. The second encoder encodes, by using a second coding scheme, a bit string formed from a specified bit in a plurality of bits allocated to each symbol in the data frame to generate the second code. The modulator performs mapping such that each pair of adjacent signal points are different from each other in terms of a value of the specified bit in the plurality of bits.

### CROSS-REFERENCE TO RELATED APPLICATION

This application is based upon and claims the benefit of priority of the prior Japanese Patent Application No. 2020-129933, filed on Jul. 31, 2020, the entire contents of which are incorporated herein by reference.

### FIELD

The embodiments discussed herein are related to a communication device and a communication method for transmitting data by using multilevel coding, and a communication system.

### BACKGROUND

Error corrections for correcting errors in data in communication systems have been widespread. An error correction is implemented by adding an error correction code to the end of a transmission frame. In particular, a transmission device on the transmission side adds an error correction code to the end of a transmission frame including data. A communication device on the reception side detects whether there is an error in received data by using an error correction code. When an error is detected, the error correction code is used to correct the error.

In the meantime, the number of bits allocated to each symbol has been increasing to allow communication systems to have a larger capacity. However, when many bits are allocated to each symbol, there will be many signal points at which the symbols could be located, and the distances between the signal points will be short. Hence, an error will easily occur. For example, an error could easily occur at the least significant bit (i.e., LSB) of a plurality of bits allocated to each symbol.

Accordingly, multilevel coding may be performed in a communication system in which many bits are allocated to each symbol. As a general rule, a plurality of coding schemes with different correction capabilities are used in multilevel coding. Both data reliability and bandwidth use efficiency are improved using multilevel coding.

In proposed methods, a plurality of bits are encoded using first and second parity bits (e.g., Japanese National Publication of International Patent Application No. 2017-507510).

As indicated above, multilevel coding has attracted attention as one method for improving both data reliability and bandwidth use efficiency. However, the conventional multilevel coding may involve large power consumption.

For example, when 16 quadrature amplitude modulation (16 QAM) is used, four bits may be allocated to each symbol. Two bits are allocated to I channel, and the remaining two bits are allocated to Q channel. In this case, LSBs are encoded for the I channel by using a coding scheme with a high correction capability and also encoded for the Q channel by using a coding scheme with a high correction capability.

However, coding schemes with a high correction capability typically involve large power consumption. Especially when a decoding device recovers data by performing iterative processing using soft decision information, the iterative processing will consume a large amount of power. According to the prior art, such iterative processing is performed for both I channel and Q channel. Hence, the conventional multilevel coding may involve large power consumption.

### SUMMARY

According to an aspect of the embodiments, a communication device generates a modulated signal with quadrature amplitude modulation that allocates a plurality of bits to each symbol. The communication device includes: a modulator configured to generate a modulated signal by mapping each symbol in a data frame that includes transmission data, a first code, and a second code to a signal point among two-dimensionally arranged signal points specific to the quadrature amplitude modulation; a first encoder configured to encode the transmission data by using a first coding scheme so as to generate the first code; and a second encoder configured to encode, by using a second coding scheme different from the first coding scheme, a bit string formed from a specified bit in a plurality of bits allocated to each symbol in the data frame so as to generate the second code. The modulator performs mapping such that each pair of adjacent signal points are different from each other in terms of a value of the specified bit in the plurality of bits.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of a communication system in accordance with embodiments of the invention;

FIG. 2 illustrates a configuration example of communication system;

FIG. 3 illustrates an example of a transmitter and a receiver;

FIGS. 4A and 4B illustrate an example of mapping in a communication system depicted in FIG. 3;

FIGS. 5A-5D illustrate an example of coding in a communication system depicted in FIG. 3;

FIG. 6 illustrates an example of a decision process performed by a receiver depicted in FIG. 3;

FIG. 7 illustrates an example of a transmitter and a receiver in accordance with embodiments of the invention;

FIGS. 8A-8C illustrate an example of coding in accordance with embodiments of the invention;

FIGS. 9A and 9B illustrate an example of a mapping rule for 16 QAM;

FIG. 10 is a flowchart illustrating an example of operations of a transmitter;

FIG. 11 is a flowchart illustrating an example of operations of a receiver;

FIGS. 12A-12C illustrate an example of coding for 64 QAM;

FIG. 13 illustrates an example of a mapping rule for 64 QAM; and

FIG. 14 illustrates a mapping rule depicted in FIG. 13 separately for each bit.

### DESCRIPTION OF EMBODIMENTS

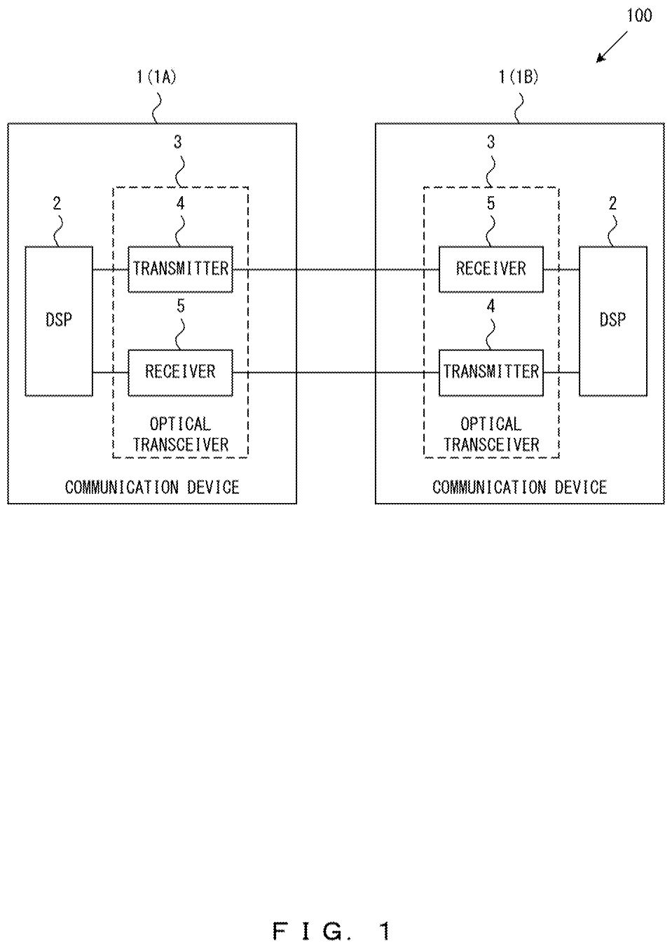

FIG. 1 illustrates an example of a communication system in accordance with embodiments of the invention. The communication system 100 includes a plurality of communication devices 1 (1A, 1B).

The communication device 1 includes a digital signal processor (DSP) 2 and an optical transceiver 3. The DSP 2 generates data to be transmitted to another communication device. The DSP 2 processes data received by the communication device 1 from another communication device. The optical transceiver 3 includes a transmitter 4 and a receiver 5. The transmitter 4 transmits data generated by the DSP 2 to another communication device. The transmitter 4 includes an encoder for encoding transmission data. The receiver 5 receives data transmitted from another communication device. The receiver 5 includes a decoder for decoding received data.

The communication system 100 transmits an optical signal with quadrature amplitude modulation. In quadrature amplitude modulation, a plurality of bits are allocated to each symbol. For example, four bits may be allocated to each symbol in 16 QAM, and six bits may be allocated to each symbol in 64 QAM. Note that QAM may be referred to as quadrature phase amplitude modulation.

In the communication system 100, transmission data is encoded using, multilevel codes. A plurality of codes with different error correction capabilities are used in multilevel coding. In this example, Bose-Chaudhuri-Hocquenghem (BCH) codes and low-density parity check (LDPC) codes are used. BCH code typically has a moderately high error correction capability but involves low power consumption. An LDPC code typically has a high error correction capability and is thus effective for a path with large noise but tends to cause a decoder circuit to consume high power. The following descriptions are based on the assumption that LDPC codes have a higher error correction capability than BCH codes.

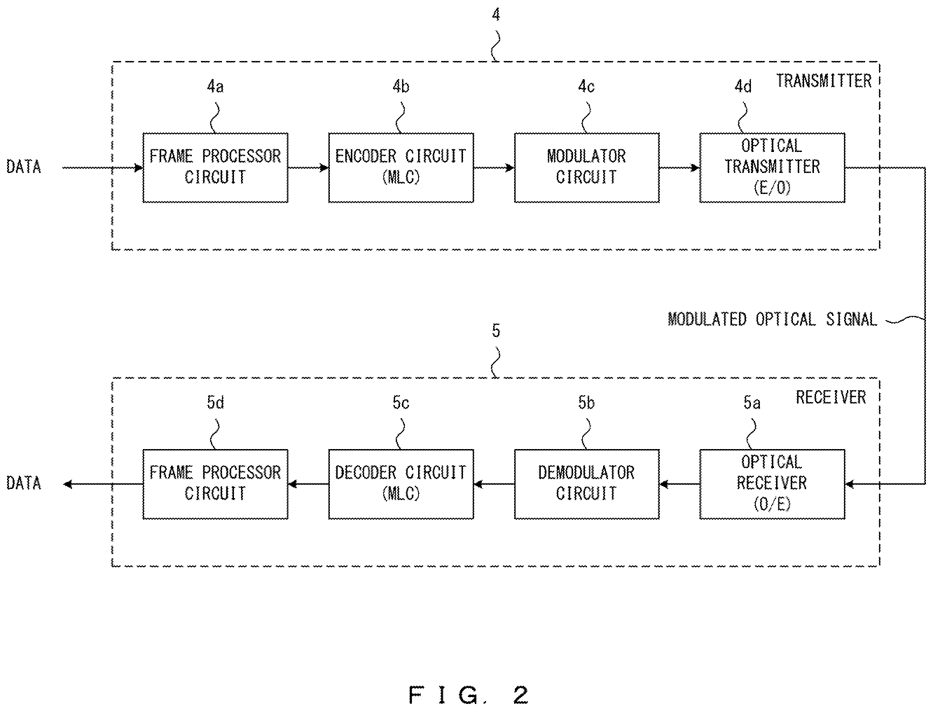

FIG. 2 illustrates a configuration example of the communication system 100. The transmitter 4 and the receiver 5 depicted in FIG. 2 may be implemented in each of the communication devices 1A and 1B in the communication system 100 depicted in FIG. 1.

The transmitter 4 includes a frame processor circuit 4a, an encoder circuit 4b, a modulator circuit 4c, and an optical transmitter 4d. The frame processor circuit 4a stores data generated by an application in a specified frame. For example, the specified frame may be, but is not particularly limited to, an optical transport network (OTN) frame. The encoder circuit 4b encodes a bit string stored in a frame. In this case, the encoder circuit 4b performs multilevel coding. The modulator circuit 4c maps, for each symbol, a bit string encoded by the encoder circuit 4b to a corresponding signal point among two-dimensionally arranged signal points. The modulator circuit 4c may have an equalizer (e.g., pre-equalization) function. The optical transmitter 4d generates a modulated optical signal in accordance with a signal point determined by the modulator circuit 4c.

The receiver 5 includes an optical receiver 5a, a demodulator circuit 5b, a decoder circuit 5c, and a frame processor circuit 5d. The optical receiver 5a converts a received optical signal into an electric signal. In this case, the optical receiver 5c may generate electric field information indicating the received optical signal. The demodulator circuit 5b demodulates a received signal. The demodulator circuit 5b may have an equalizer function. The decoder circuit 5c decodes the signal demodulated by the demodulator circuit 5b. In this case, the decoder circuit 5c performs a decoding process corresponding to multilevel coding performed by the encoder circuit 4b. The decoder circuit 5c performs an error correction. The frame processor circuit 5d.processes a received frame.

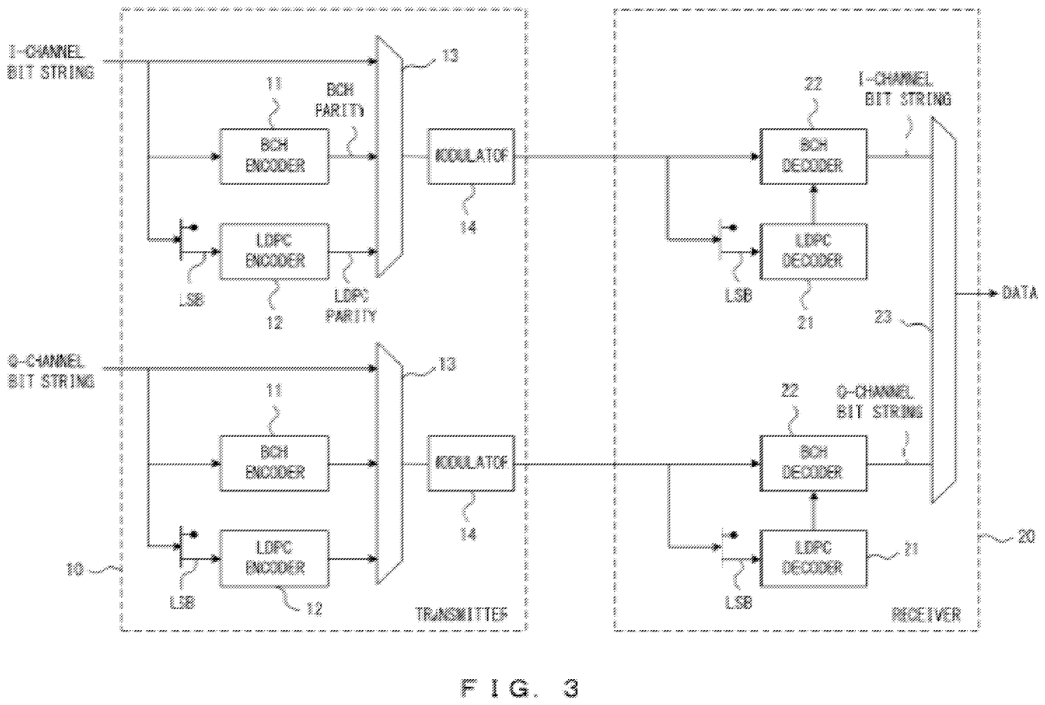

FIG. 3 illustrates an example of the transmitter and the receiver used in the communication system 100. The transmitter 10 and the receiver 20 depicted in FIG. 3 respectively correspond to the transmitter 4 implemented in the communication device 1A and the receiver 5 implemented in the communication device 1B in the communication system 100 depicted in FIG. 1,

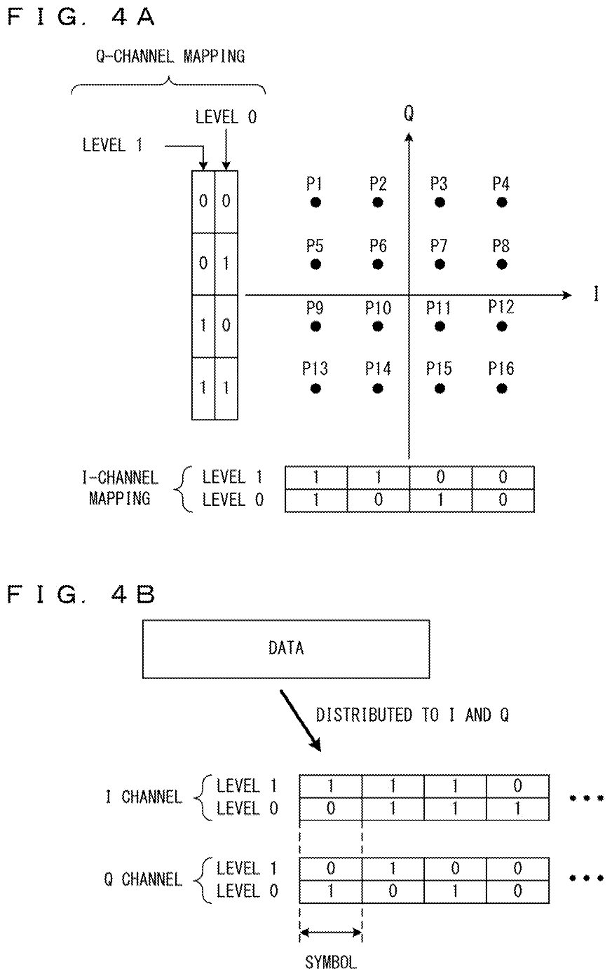

FIGS. 4A and 4B illustrate an example of mapping in the communication system depicted in FIG. 3. The transmitter 10 transmits data with quadrature amplitude modulation. In this example, the transmitter 10 transmits data with 16 QAM. In 16 QAM, four bits are allocated to each symbol. Thus, each symbol carries four bits. Accordingly, 16 QAM uses 16 signal points depicted in FIG 4A. A transmission symbols is mapped to a signal point corresponding to a 4-bit value forming the symbol. In this case, four bits of data are transmitted using a pair of channels (I and Q) orthogonal to each other. In particular, as depicted in FIG 4B, two of four bits indicating each symbol are allocated to the I channel, and the remaining two bits are allocated to the Q channel. Data transmitted using the I channel may hereinafter be referred to as an I-channel bit string. Data transmitted using the Q channel may hereinafter be referred to as a Q-channel bit string.

Assume, for example, that four bits allocated to a transmission symbol is “1001,” as depicted in FIG. 4B and that the high two bits “10” are allocated to the I channel and the low two bits “01” are allocated to the Q channel. In this case, mapping is performed for each of the I channel and the Q channel. In the example depicted in FIG. 4A, a signal point P2, P6, P10, or P14 is selected when the data of the I channel is “10.” The signal point P5, P6, P7, or P8 is selected when the data of the Q channel is “01.” Thus, the transmission symbol is mapped to the signal point P6 selected by both the data of the I channel and the data of the Q channel. In this case, the symbol “1001” is transmitted using a phase and an amplitude that correspond to the signal point P6.

As described above, the transmitter 10 separately processes an I-channel bit string and a Q-channel bit string. Accordingly, as depicted in FIG. 3, the transmitter 10 includes, for each of the channels, a BCH encoder 11, an LDPC encoder 12, a frame generator 13, and a modulator 14.

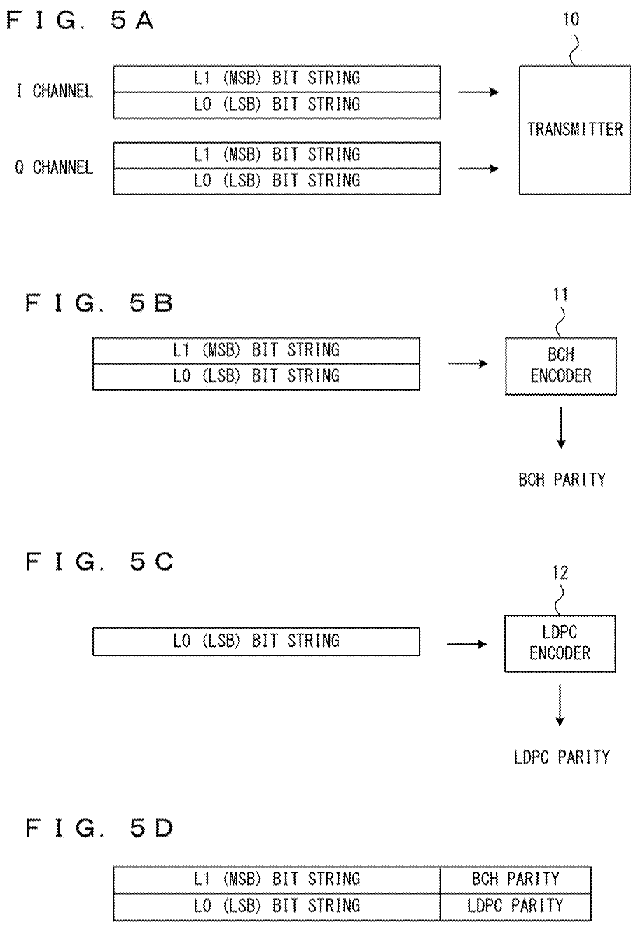

FIGS. 5A-5D illustrate an example of coding in the communication system depicted in FIG. 3. As depicted in FIG. 5A, transmission data is separated into an I-channel bit string and a Q-channel bit string and supplied to the transmitter 10. The bit string of each channel is formed from an L0 bit string (i.e., LSB bit string) and an L1 bit string (i.e., MSB bit string).

As depicted in FIG. 5B, the BCH encoder 11 generates a BCH parity by performing BCH coding for an L0 bit string and an L1 bit string. The BCH parity is an example of a BCH code. As depicted in FIG. 5C, the LDPC encoder 12 generates an LDPC parity by performing LDPC coding for an L0 bit string. The LDPC parity is an example of an LDPC code.

The frame generator 13 generates a transmission data frame by adding a BCH parity and an LDPC parity to input bit strings. In this case, as depicted in FIG. 5D, the LDPC parity is added to an L0 bit string. The BCH parity is added to an L1 bit string. The modulator 14 maps each of the symbols in the data frame output from the frame generator 13 to a corresponding signal point. The mapping follows the rule indicated in FIG. 4A.

The transmitter 10 determines one signal point in accordance with the mapping for the I channel and the mapping for the Q channel. The transmitter 10 transmits a symbol by means of the determined signal point. An optical signal output from the transmitter 10 is transmitted to the receiver 20 via an optical transmission line. Although FIG. 3 illustrates that the I channel and the Q channel are separated from each other, a 16 QAM signal obtained by combining the I channel and the Q channel will be transmitted in reality.

The receiver 20 includes an LDPC decoder 21, a BCH decoder 22, and a frame generator 23. As with the transmitter 10, the receiver 20 performs a decoding process for each of the I channel and the Q channel.

The LDPC decoder 21 performs LDPC decoding for a received signal. LDPC decoding is performed for an L0 bit string. As a result, the L0 bit string will be recovered. The BCH decoder 22 performs BCH decoding for the received signal by using the L0 bit string recovered by the LDPC decoder 21. As a result, the L0 bit string and an L1 bit string will be recovered. These decoding processes are performed for each of the channels. Thus, an I-channel bit string and a Q-channel bit string are recovered. Then, transmission data is recovered from the I-channel bit string and the Q-channel bit string.

As described above, in the communication system 100, data is transmitted by means of multilevel coding. Note that when deciding symbols, an error tends to occur in LSBs (L0 bits in this example) more easily than in MSBs (L1 bits in this example).

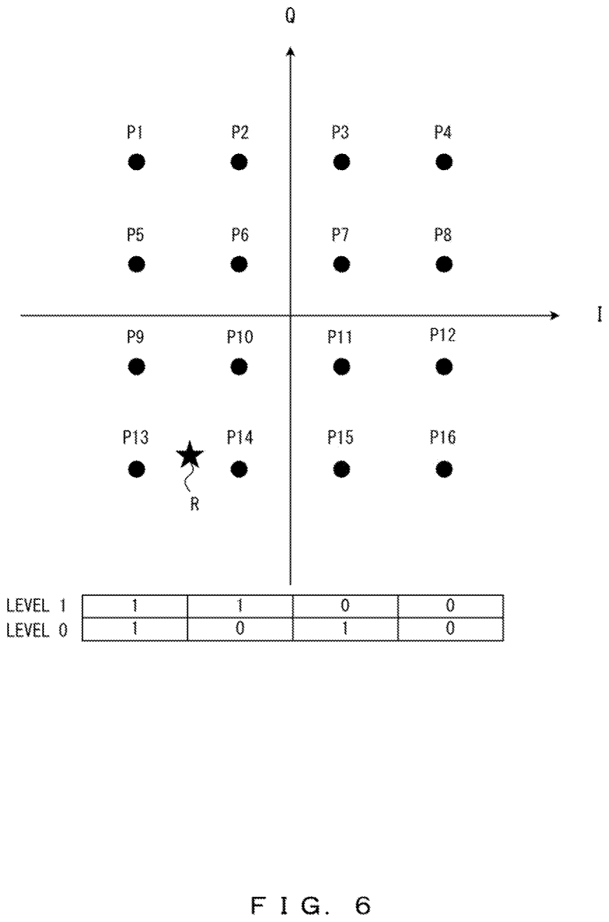

FIG. 6 illustrates an example of a decision process performed by the receiver depicted in FIG. 3. Assume, for example, that a symbol transmitted from the transmitter 10 by using the signal point P13 indicated in FIG. 6 has been detected at a reception point R by the receiver 20. In this case, the receiver 20 decides data allocated to the received symbol by detecting the closest signal point to the reception point R. For example, in the decision for the I channel, the distance between the reception point R and the signal point P13 may be compared with the distance between the reception point R and the signal point P14. Assume that the incorrect decision result (i.e., signal point P14) is obtained. In this case, even though the transmission data of the I channel is “11,” the receiver 20 will recover “10.” That is, the LSB is incorrect. However, both of the MSBs of the signal points P13 and P14 are “1,” and as error will not occur. Thus, an error tends to occur at the LSB more easily than the other bits (in this case, MSB).

Accordingly, multilevel coding is such that a coding scheme with a high error correction capability is used for a bit string in which an error tends to occur. Thus, an LDPC code is used for an LSB bit string. Hence, data reliability is enhanced.

However, coding schemes with a high correction capability typically involve large power consumption. For example, data encoded by LDPC codes may preferably be recovered through iterative processing using soft decision information. The iterative processing involves large power consumption.

The transmitter 10 depicted is FIG. 3 performs coding for each of the I channel and the Q channel. The receiver 20 depicted in FIG. 3 performs decoding for each of the I channel and the Q channel. Hence, for example, the communication system 100 using 16 QAM may perform LDPC coding for one of two bits for the I channel and perform LDPC coding for one of two bits for the Q channel. Thus, LDPC coding is performed for two of four bits allocated to each symbol, thereby increasing power consumption.

### Embodiments

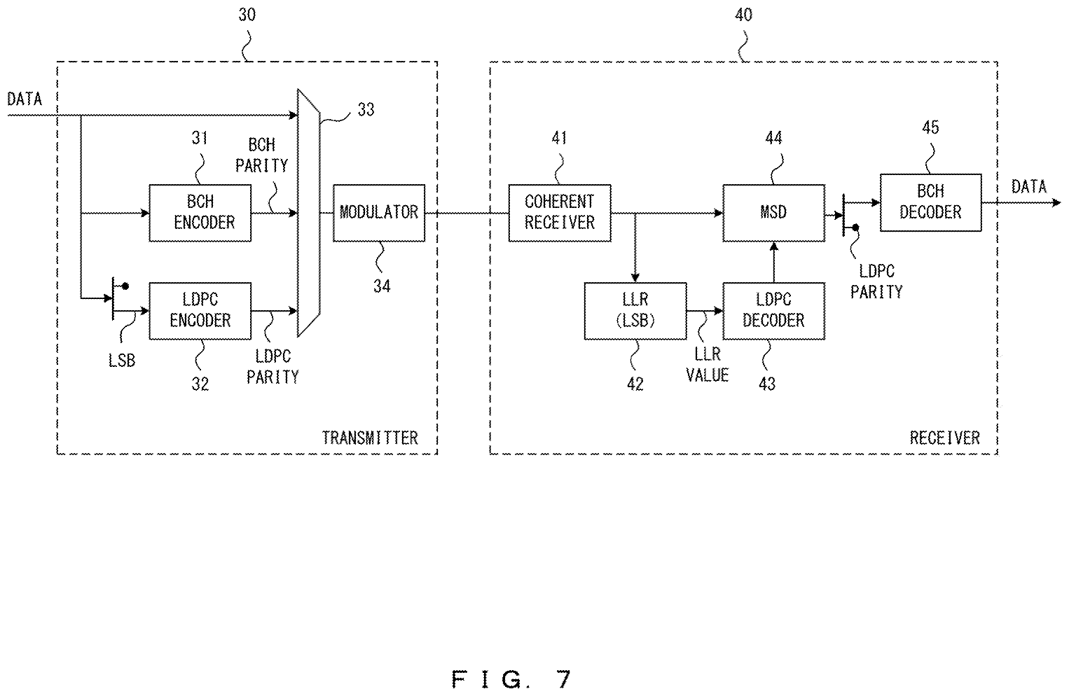

FIG. 7 illustrates an example of a transmitter and a receiver in accordance with embodiments of the invention. The transmitter 30 and the receiver 40 depicted in FIG. 7 respectively correspond to the transmitter 4 implemented in the communication device 1A and the receiver 5 implemented in the communication device 1B in the communication system 100 depicted in FIG. 1. In this example, the transmitter 30 transmits data with 16 QAM. In 16 QAM, four bits are allocated to each symbol. Thus, each symbol carries four bits.

The transmitter 30 includes a BCH encoder 31, an LDPC encoder 32, a frame generator 33, and a modulator 34. Although the transmitter 10 depicted in FIG. 3 includes two BCH encoders 11, two LDPC encoders 12, two frame generators 13, and two modulators 14, the transmitter 30 in accordance with embodiments of the invention includes one BCH encoder 31, one LDPC encoder 32, one frame generator 33, and one modulator 34.

Operations of the BCH encoder 31, the LDPC encoder 32, the frame generator 33, and the modulator 34 are almost the same as those of the BCH encoders 11, the LDPC encoders 12, the frame generators 13, and the modulators 14 depicted in FIG. 3. However, while the configuration depicted in FIG. 3 is such that the I channel and the Q channel are individually coded, embodiments of the present invention are such that transmission data coded without being divided into an I channel and a Q channel.

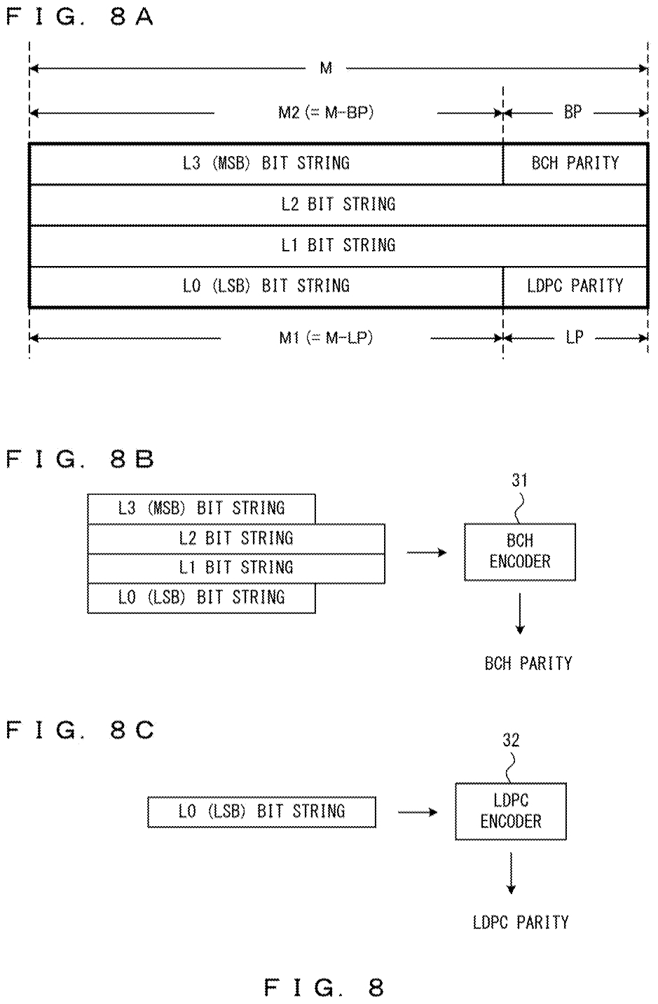

FIGS. 8A-8C illustrate an example of coding in accordance with embodiments of the invention. For example, although not particularly limited, transmission data may be stored in a data frame depicted in FIG. 8A and transmitted from the transmitter 30 to the receiver 40. Since 16 QAM transmits four bits per symbol, the data frame is formed from four bit levels (L0-L3). The length of the data frame is M symbols.

Transmission data is stored in a level L0 region to a level L3 region. However, LDPC parity bits are stored in a portion of the level L0 region. When the length of the LDPC parity bits is LP bits, (M-LP) bits of data are stored in the level L0 region. BCH parity bits are stored in a portion of the level L3 region. When the length of the BCH parity bits is BP bits, (M-BP) bits of data are stored in the level L3 region. Thus, the data frame stores (4M-LP-BP) bits of transmission data.

Accordingly, when transmission data generated by an application is greater than (4M-LP-BP) bits, the transmission data will be supplied (4M-LP-BP) bits at a time to the transmitter 30. When transmission data is less than (4M-LP-BP) bits, a dummy bit or padding may be added to the transmission data. The data input to the transmitter 30 is guided to the BCH encoder 31, the LDPC encoder 32, and the frame generator 33.

The BCH encoder 31 generates a BCH parity by performing BCH coding for transmission data. In particular, as depicted in FIG. 8B, the BCH encoder 31 generates a BCH parity by performing BCH coding for an L0 (LSB) bit string, an L1 bit string, an L2 bit string, and an L3 (MSB) bit string. Note that a code rate may be determined in advance. The BCH parity is an example of a BCH code. For example, the BCH encoder 31 may be implemented by a digital circuit that generates a BCH parity by performing BCH coding for an input bit string. However, the encoder 31 may be implemented by a processor executing a software program.

The LDPC encoder 32 generates an LDPC parity by encoding a bit string formed from a specified bit among four bits allocated to each symbol in transmission data. For example, the specified bit may be a least significant bit (LSB). In this case, as depicted in FIG. 8C, the LDPC encoder 32 generates an LDPC parity by performing LDPC coding for an L0 bit string. Note that the code rate may be determined in advance. The LDPC parity is an example of an LDPC code. For example, the LDPC encoder 32 be implemented by digital circuit that generates an LDPC parity by performing LDPC coding for the L0 (LSB) bit string in transmission data. However, the LDPC encoder 32 may be implemented by a processor executing a software program.

The frame generator 33 generates a data frame including transmission data (L0-L3 bit strings), a BCH parity, and an LDPC parity. Accordingly, the data frame depicted in FIG. 8A is generated from transmission data, a BCH parity, and an LDPC parity. In this case, the LDPC parity generated for the L0 (LSB) bit string is stored in the level L0 region. Thus, the LDPC parity is transmitted using the LSB. The BCH parity is stored in a region other than the level L0 region. Thus, the BCH parity is transmitted using a bit other than the L0 bit. In this example, the BCH parity is transmitted using the L3 (MSB) bit. The frame generator 33 is implemented by a digital circuit that generates data frames in the above-described manner. However, the frame generator 33 may be implemented by a processor executing a software program.

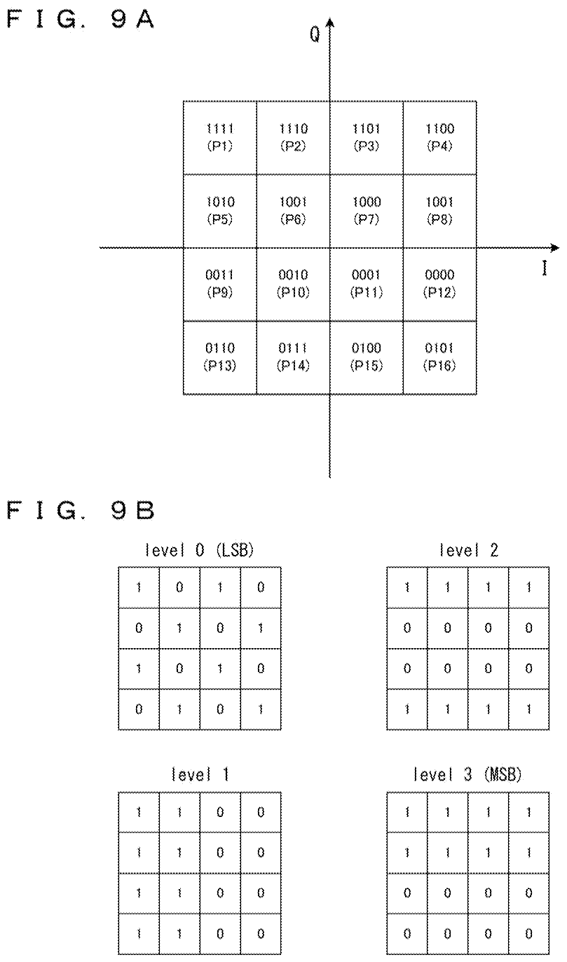

FIGS. 9A and 9B illustrate an example of a mapping rule according to 16 QAM. The modulator 34 generates a modulated signal by mapping the symbols in a data frame generated by the frame generator 33 to signal points of 16 QAM. In particular, in accordance with the mapping rule depicted in FIG. 9A, transmission symbols are two-dimensionality mapped to signal points each corresponding to a four-bit value forming a symbol. For example, a transmission symbol formed from four bits of “0110” may be mapped to the signal point P13. For example, a transmission symbol formed from four bits of “0111” may be mapped to the signal point P14. In this example, a left end bit is an MSB (L3 bit), and a right end bit is an LSB (L0 bit).

As indicated in FIG. 9B, the modulator 34 performs mapping such that each pair of adjacent signal points are different from each other in terms of the values of L0 bits. That is, values of L0 bits of arbitrary adjacent signal points are different from each other. For example, the signal points P13 and P14 are adjacent to each other in an I-axis direction. The LSB of a symbol mapped to the signal point P13 is “0,” and the LSB of a symbol mapped to the signal point P14 is “1.” The signal points P9 and P13 are adjacent to each other in a Q-axis direction. The LSB of a symbol mapped to the signal point P9 is “1,” and the LSB of a symbol mapped to the signal point P13 is “0.” In this way, the modulator 34 performs mapping such that each pair of signal points adjacent to each other in any of the directions of coordinate axes in the two-dimensional coordinate in which 16 signal points corresponding to 16 QAM are arranged are different fro each other it terms of the value of a specified one bit (least significant bit in examples) among four bits forming a symbol.

For the other bits (L1-L3), as depicted in FIG. 9B, mapping is performed such that the values are equal as much as possible between adjacent signal points. In this example, for the L1 (level 1) bits, signal-point values belonging to the two columns on the negative side are “1,” and signal-point values belonging to the two columns on the positive side are “0.” For the L2 (level 2) bits, signal point values belonging to the first and fourth rows are “1,” and signal-point values belonging to the second and third rows are “0.” For the L3 (MSB: level 3) bits, signal-point values belonging to the first and second rows are “1,” and signal-point values belonging to the third and fourth rows are “0.” For the L1-L3 bits, it is also preferable that the values be equal as much as possible between signal points diagonally adjacent to each other.

The modulator 34 generates, for each transmission symbol, an optical signal having an amplitude and a phase that correspond to a signal point to which the transmission symbol is mapped. The optical signal is transmitted to the receiver 40 via an optical transmission line. In the meantime, the modulator 34 includes a circuit for generating a drive signal representing a determined signal point and an optical modulator for generating an optical signal based on the drive signal.

Note that the BCH encoder 31 and the LDPC encoder 32 correspond to the encoder circuit 4b depicted in FIG. 2.

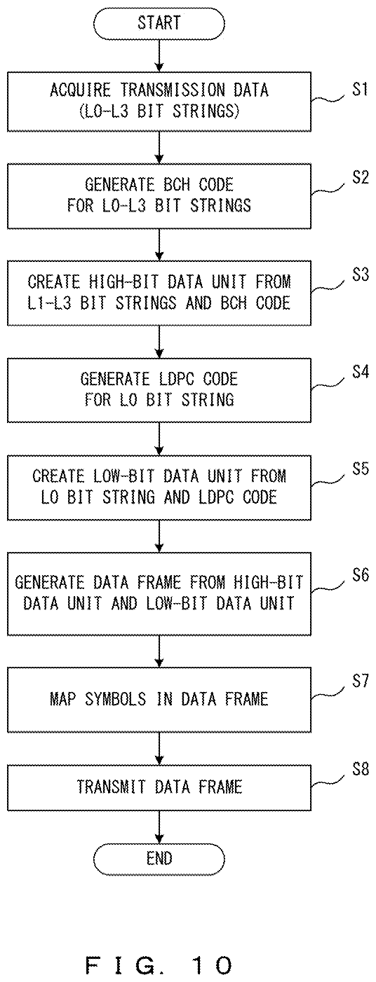

FIG. 10 is a flowchart illustrating an example of operations of the transmitter 30. The processes of this flowchart are performed when the communication device 1 has generated transmission data. Alternatively, the transmitter 30 may perform the processes of the flowchart depicted in FIG. 10 when probabilistic shaping (PS) is not performed.

In S1, the transmitter 30 acquires transmission data. The transmission data corresponds to the L0-L3 bit strings depicted in FIG. 8A. In S2, the BCH encoder 31 generates a BCH parity (or BCH code) by performing BCH coding for the L0-L3 bit strings. In S3, the frame generator 33 generates a high-bit data unit for a data frame from the L1-L3 bit strings and the BCH code. In particular, the frame generator 33 creates a level L1 region, a level L2 region, and a level L3 region for the data frame by storing the L1 bit string in the level L1 region, storing the L2 bit string in the level L2 region, and storing the L3 bit string and the BCH parity in the level L3 region.

In S4, the LDPC encoder 32 generates an LDPC parity (or LDPC code) by performing LDPC coding for the L0 bit string. In S5, the frame generator 33 generates a low-bit data unit for the data frame from the L0 bit string and the LDPC code. In particular, the frame generator 33 creates a level L0 region for the data frame by storing the L0 bit string and the LDPC parity in the level L0 region.

In S6, the frame generator 33 generates the data frame from the high-bit data unit created through S2-S3 and the low-bit data unit created through S4-S5. In S7, the modulator 34 maps each of the symbols in the data frame to a corresponding signal point. In this case, for example, each of the symbols may be mapped to a corresponding signal point in accordance with the mapping rule depicted in FIGS. 9A and 9B. In S3, the transmitter 30 sequentially transmits the symbols in the data frame.

The receiver 40 includes a coherent receiver 41, a log-likelihood-ratio (LLR) calculator 42, an LDPC decoder 43, a multi-stage decoder (MSD) 44, and a BCH decoder 45. The receiver 40 receives a data frame transmitted from the transmitter 30.

The coherent receiver 41 generates electric field information indicating a received optical signal. In particular, the coherent receiver 41 generates electric field information indicating the phases and amplitudes of received symbols. The coherent receiver 41 includes a local light source, a 90-degree optical hybrid circuit, an optical receiver circuit, and the like. The coherent receiver 41 may have a function for compensating for dispersion in an optical transmission line, a function for compensating for the difference between the carrier frequency of an optical signal and the frequency of the local light source, and the like.

The LLR calculator 42 calculates the value of a log likelihood ratio (LLR) by performing a soft decision for a received signal. In particular, the LLR calculator 42 calculates the LLR values of received symbols. However, the LLR calculator 42 does not calculate LLR values for all bits of each of the received symbols but calculates LLR values only for the LSBs of the received symbols. Thus, in the case of the data frame depicted in FIG. 8A, an LLR value is calculated for the bits in the L0 (LSB) bit string and the LDPC parity.

An LLR value indicates the logarithm of the ratio between the probability that a received signal was “1” at a transmitter and the probability that the received signal was “0” at the transmitter. Thus, the LLR value is calculated according to reception electric field information indicating the phase and amplitude of a received symbol. In particular, the LLR value is calculated according to the distances between the received symbol, and signal points (16 signal points in the case of 16 QAM). In the meantime, the LLR calculator 42 is implemented by, for example, a digital circuit that calculates an LLR value. In this case, the digital circuit may include a circuit for storing a relation between the electric field information and the LLR value of a received symbol. The LLR calculator 42 may also be implemented by a processor executing a software program.

The LDPC decoder 43 performs LDPC decoding based on a soft decision result output from the LLR calculator 42. In particular, the LDPC decoder 43 performs LDPC decoding by using the LLR value of the bits in the L0 (LSB) bit string and the LDPC parity. In this case, the LDPC decoder 43 performs, for example, probability propagation decoding. A probability propagation decoding algorithm includes iterative processing of updating the LLR value of the bits until a parity check is satisfied. Decision results obtained for the bits when the parity check is satisfied are output as decoding results. As a result, the bits in the L0 (LSB) bit string and the LDPC parity are recovered. Note that the probability propagation decoding algorithm may stop the iterative processing when the number of iterations has reached a specified maximum value. In this case, the bits in the L0 (LSB) bit string and the LDPC parity are decided according to the updated LLR value of the bits obtained when the iterative processing reaches the specified maximum value. In the meantime, the LDPC decoder 43 is implemented by, for example, a digital circuit that performs the decoding process. However, the LDPC decoder 43 may be implemented by a processor executing a software program.

The multi-stage decoder 44 demaps received symbols according to electric field information indicating received optical signal. In this case, the multi-stage decoder 44 converts each received symbol into four bits of data in accordance with the mapping rule depicted in FIGS. 9A and 9B. However, the L0 bit of the four bits forming each symbol has been decided by the LDPC decoder 43. Accordingly, the multi-stage decoder 44 demaps the received symbols by using decision results provided by the LDPC decoder 43.

Assume, for example, that, a received symbol has been detected at the point R depicted in FIG. 6. In this case, the multi-stage decoder 44 detects the closest signal point to the reception point R so as to decide the signal point used by the transmitter 30. However, in this example, the distance between the reception point R and the signal point P13 and the distance between the reception point R and the signal point P14 are almost equal. Thus, an incorrect decision result could be obtained if a decision result provided by the LDPC decoder 43 is not used.

Accordingly, the multi-stage decoder 44 uses a decision result provided by the LDPC decoder 43. In this example, the decision result provided by the LDPC decoder 43 is “0.” That is, the least significant bit of the four bits corresponding to the received symbol is “0.” Since the LDPC decoder 43 performs a parity check, the reliability of the decision result provided by the LDPC decoder 43 is high. Meanwhile, as depicted in FIG. 9A, the high three bits of the four bits corresponding to each of the signal points P13 and P14 are “O11.” Thus, the decision result of the received symbol is “0110.” In this example, high bits are mapped such that values are equal as much as possible between adjacent signal points, as described above by referring to FIGS. 9A and 9B. Hence, the probability of occurrence of an error in the abovementioned bits will be low.

The symbols in a data frame are decided in the manner described above. Specifically, the L0-L3 bit strings, the LDPC parity, and the BCH parity depicted in FIG. 8A are recovered.

The BCH decoder 45 performs BCH decoding for a decision result provided by the multi-stage decoder 44. However, the transmitter 30 generates a BCH parity for L0-L3 bit strings. Thus, an LDPC parity is discarded, and the BCH decoder 45 uses the BCH parity so as to check the L0-L3 bit strings output from the multi-stage decoder 44. In this case, any errors detected will be corrected. As a result, transmission data will be recovered. In the meantime, the BCH decoder 45 is implemented by, for example, a digital circuit that performs the decoding process. However, the BCH decoder 45 may be implemented by a processor executing a software program.

As described above, the receiver 40 depicted in FIG. 7 collectively decodes a plurality of bits forming each received symbol, unlike the receiver 2C depicted in FIG. 3. Thus, the receiver 40 depicted in FIG. 7 has fewer bits for which iterative processing using soft decision information is performed than the receiver 20 depicted in FIG. 3. In particular, the receiver 20 depicted in FIG. 3 performs, for each of the I channel and the Q channel, the iterative processing using soft decision information for one of two bits. That is, the receiver 20 depicted in FIG. 3 performs the iterative processing using soft decision information for two of four bits. On the other hand, the receiver 40 depicted in FIG. 7 performs the iterative processing using soft decision information for one of four bits. In this regard, the iterative processing using soft decision information involves large power consumption. Accordingly, embodiments of the invention have reduced power consumption in multilevel coding communication.

The LLR calculator 42, the LDPC decoder 43, the multi-stage decoder 44, and the BCH decoder 45 correspond to the decoder circuit 5c depicted in FIG. 2. The coherent receiver 41 corresponds to the optical receiver 5a and the demodulator circuit 5b depicted in FIG. 2.

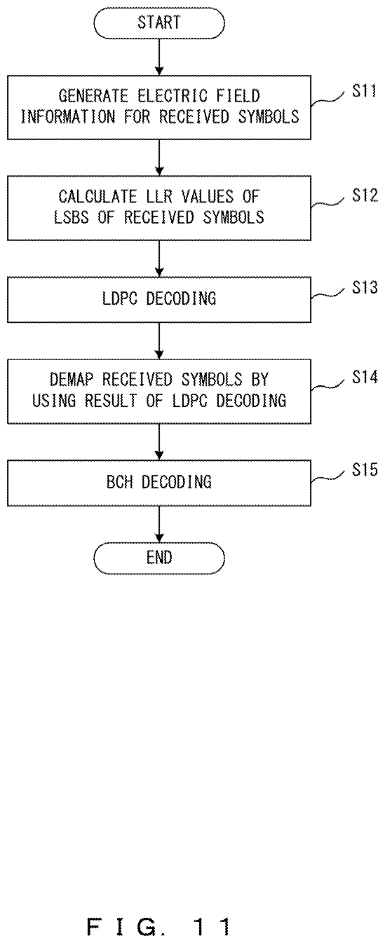

FIG. 11 is a flowchart illustrating an example of operations of the receiver 40. The receiver 40 receives an optical signal transmitted from the transmitter 30 depicted in FIG. 7.

In S11, the coherent receiver 41 generates electric field information for received symbols. The electric field information indicates the phases and amplitudes of the received symbols. In S12, the LLR calculator 42 performs a soft decision for each of the received symbols according to the electric field information indicating the received optical signal. In particular, the LLR values of the received symbols are calculated. However, the LLR calculator 42 may calculate LLR values only for the LSBs of the received symbols.

In S13, the LDPC decoder 43 performs LDPC decoding based on a soft decision result output from the LLR calculator 42. As a result, the bits in an L0 bit string and an LDPC parity are recovered. In S14, the multi-stage decoder 44 demaps the received symbols according to the electric field information indicating the received optical signal. In this case, the multi-stage decoder 44 demaps the received symbols by using a decision result provided by the LDPC decoder 43. Aa result, the bits in the L0-L3 bit strings and the BCH parity are recovered. In S15, the BCH decoder 45 uses the BCH parity so as to decode the L0-L3 bit strings output from the multi-stage decoder 44. In particular, error detection and error correction are performed tor the L0-L3 bit strings by using the BCH parity. As a result, the transmission data is recovered.

### Variation

In the examples described above, data is transmitted with 16 QAM. However, the present invention is not limited to this. In particular, embodiments of the invention can be applied to any quadrature amplitude modulation. Specifically, embodiments of the invention can be applied to quadrature amplitude modulation in which N (N is an Integer larger than or equal to 4) bits are allocated to each symbol.

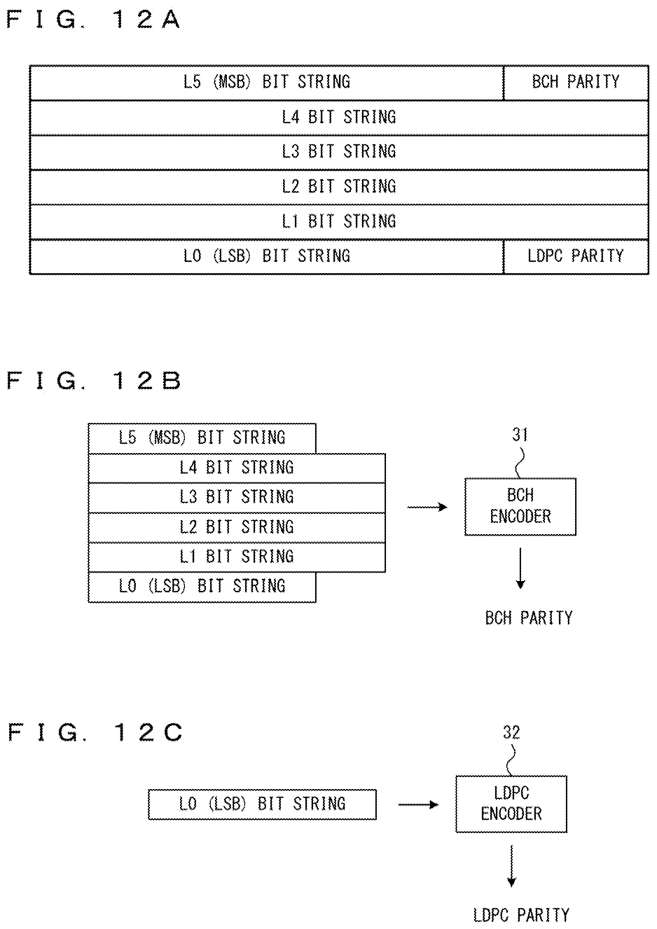

FIGS. 12A-12C illustrate an example of coding according to 64 QAM. For example, in 64 QAM, six bits are allocated to each symbol. Thus, in a 64 QAM communication system, a transmitter 30 transmits a data frame depicted in FIG. 12A to a receiver 40. In this case, BCH encoder 31 generates a BCH parity by performing BCH coding for input bit strings (i.e., L0-L5 bit strings), as depicted in FIG. 12B. The LDPC encoder 32 generates an LDPC parity by performing LDPC coding for the L0 (LSB) bit string of the input bit strings, as depicted in FIG. 12C. The BCH parity and the LDPC parity are respectively stored in the level L5 region and the level L0 region in the data frame.

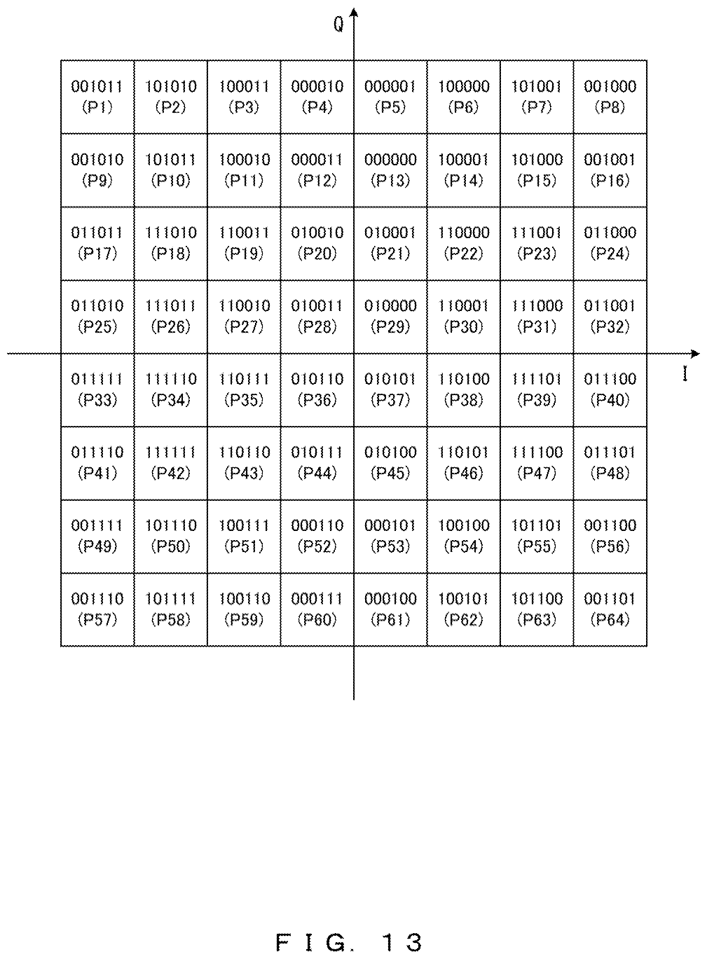

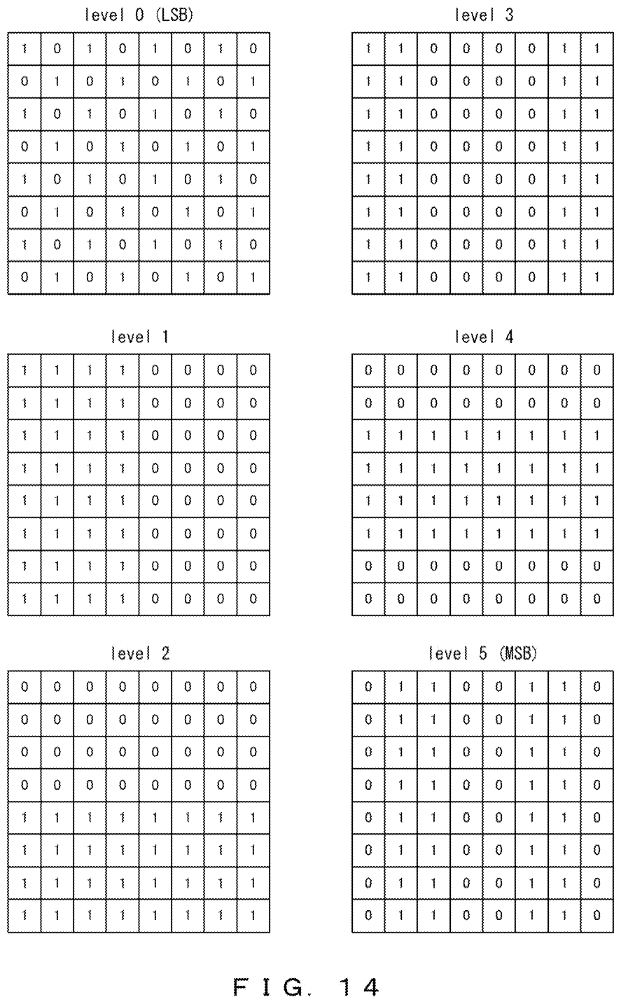

FIG. 13 illustrates an example of a mapping rule for 64 QAM. FIG. 14 illustrates the mapping rule depicted in FIG. 13 separately for each bit.

As in the case of 16 QAM, mapping is also performed in 64 QAM such that the values of L0 bits are different between adjacent signal points. For the other bits (L1-L5), mapping is performed such that the values are equal as much as possible between adjacent signal points.

Flowcharts indicating operations of the transmitter 30 are substantially the same for 16 QAM and 64 QAM. However, the 64 QAM communication system is such that the transmitter 30 acquires L0-L5 bit strings in S1, the BCH encoder 31 generates BCH codes for the L0-L5 bit strings in S2, and the frame generator 33 generates a high-bit data unit from the L0-L5 bit strings and the BCH parity in S3.

Flowcharts indicating operations of the receiver 40 are substantially the same for 16 QAM and 64 QAM. However, the 64 QAM communication system is such that the multi-stage decoder 44 recovers the bits in L0-L5 bit strings and a BCH parity in S14, and the BCH decoder 45 decodes the L0-L5 bit strings by using the BCH parity in S15.

In the examples described above, multiple coding uses BCH code and LDPC code. However, the invention is not limited to this method. In particular, the communication system 100 can use a plurality of desired coding schemes for multilevel coding. However, the communication system 100 preferably uses two coding schemes with different error correction capabilities. In this case, for example, Reed-Solomon code may be used instead of BCH code. For example, turbo code may be used instead of LDPC code. Furthermore, signals that have been encoded using a coding scheme with a high error correction capability is preferably decoded by the receiver 40 through iterative processing using soft decision information.

In the examples described above, LDPC code is used for least significant bits. However, the invention is not limited to this configuration. In particular, an LDPC code may be used for any one of a plurality of bits allocated to each symbol.

In the examples described above, the coding scheme for encoding least significant bits has a higher error correction capability than the coding scheme for encoding the entirety of data. However, the invention is not limited to this configuration. In particular, the only requirement is that the coding scheme for encoding the entirety of data be different from the coding scheme for encoding least significant bits.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. A communication system in which data is transmitted from a first communication device to a second communication device with quadrature amplitude modulation allocating a plurality of bits to each symbol, wherein
the first communication device includes:
a modulator configured to generate a modulated signal by mapping each symbol in a data frame that includes the data, a first code, and a second code to a signal point among two-dimensionally arranged signal points specific to the quadrature amplitude modulation;
a first encoder configured to encode the data by using a first coding scheme so as to generate the first code; and
a second encoder configured to encode, by using a second coding scheme different from the first coding scheme, a bit string formed from a specified bit in a plurality of bits allocated to each symbol in the data frame so as to generate the second code,
the second communication device includes a decoder configured to perform, for the modulated signal, a decoding process based on the first coding scheme and a decoding process based on the second coding scheme so as to recover the data, and
the modulator performs mapping such that each pair of adjacent signal points are different from each other in terms of a value of the specified bit in the plurality of bits.

2. A communication device for generating a modulated signal with quadrature amplitude modulation allocating a plurality of bits to each symbol, the communication device comprising:
a modulator configured to generate a modulated signal by mapping each symbol in a data frame that includes transmission data, a first code, and a second code to a signal point among two-dimensionally arranged signal points specific to the quadrature amplitude modulation;
a first encoder configured to encode the transmission data by using a first coding scheme so as to generate the first code; and
a second encoder configured to encode, by using a second coding scheme different from the first coding scheme, a bit string formed from a specified bit in a plurality of bits allocated to each symbol in the data frame so as to generate the second code, wherein
the modulator performs mapping such that each pair of adjacent signal points are different from each other in terms of a value of the specified bit in the plurality of bits.

3. The communication device according to claim 2, further comprising:
a frame generator configured to generate the data frame that includes the transmission data, the first code generated by the first encoder, and the second code generated by the second encoder, wherein
the frame generator disposes the second code at the specified bit in the data frame.

4. The communication device according to claim 3, wherein
the frame generator disposes the first code at a bit in the data frame other than the specified bit.

5. The communication device according to claim 2, wherein
the specified bit is a least significant bit of the plurality of bits.

6. The communication device according to claim 2, wherein
the quadrature amplitude modulation is 16 QAM in which four bits are allocated to each symbol or 64 QAM in which six bits are allocated to each symbol.

7. A communication device for receiving data transmitted from a transmitter with quadrature amplitude modulation allocating a plurality of bits to each symbol, wherein
the transmitter includes
a modulator configured to generate a modulated signal by mapping each symbol in a data frame that includes the data, a first code, and a second code to a signal point among two-dimensionally arranged signal points specific to the quadrature amplitude modulation,
a first encoder configured to encode the data by using a first coding scheme so as to generate the first code, and
a second encoder configured to encode, by using a second coding scheme different from the first coding scheme, a bit string formed from a specified bit in a plurality of bits allocated to each symbol in the data frame so as to generate the second code,
the modulator performs mapping such that each pair of adjacent signal points are different from each other in terms of a value of the specified bit in the plurality of bits, and
the communication device includes
a second decoder configured to decode, using the second cooing scheme, a bit string formed from the specified bit in the plurality of bits allocated to each symbol in the data frame,
a decision unit configured to decide each symbol in the data frame by using a decoding result provided by the second decoder so as to recover the data, the first code, and the second code, and
a first decoder configured to decode the recovered data based on the recovered first code by using the first coding scheme.

8. A communication method for transmitting data quadrature amplitude modulation allocating a plurality of bits to each symbol, the communication method comprising:
encoding transmission data by using first coding scheme so as to generate a first code;
encoding, by using a second coding scheme different from the first coding scheme, a bit string formed from a specified bit in a plurality of bits allocated to each symbol in a data frame so as to generate a second code;
generating the data frame from the transmission data, the first code, and the second code;
generating a modulated signal by mapping each symbol in the data frame to a signal point among two-dimensionally arranged signal points specific to the quadrature amplitude modulation, in accordance with a mapping rule in which each pair of adjacent signal points are different from each other in terms of a value of the specified bit in the plurality of bits; and
transmitting the modulated signal.
